(19) United States
(12) Patent Application Publication
(10) Pub. No.: US 2016/0157394 A1
(43) Pub. Date: Jun. 2, 2016

(54) MAGNETIC SHIELDING

(71) Applicant: COMMISSARIAT À L'ENERGIE ATOMIQUE ET AUX ENERGIES ALTERNATIVES, Paris (FR)

(72) Inventors: Matthieu LE PRADO, Saint-Marcellin (FR); Sophie MORALES, Varces (FR); Marie-Constance CORSI, Grenoble (FR); Antonio VIANA, Herbeys (FR)

(73) Assignee: COMMISSARIAT À L'ENERGIE ATOMIQUE ET AUX ENERGIES ALTERNATIVES, Paris (FR)

(21) Appl. No.: 14/954,437

(22) Filed: Nov. 30, 2015

(30) Foreign Application Priority Data
Nov. 28, 2014 (FR) 14 61625

(51) Int. Cl. H05K 9/00

(52) U.S. Cl. CPC H05K 9/0081; H05K 9/0075

(57) ABSTRACT

A magnetic shielding including at least one side wall defining a cavity to contain an object to be magnetically isolated. The side wall includes between three and five layers of ferromagnetic metallic material and between three and five layers of polymer material including a ferromagnetic powder. Two adjacent metallic layers are separated by a polymer material layer.

### BACKGROUND OF THE INVENTION

The invention relates to a magnetic shielding device having an improved impact resistance.

### STATE OF THE ART

A magnetic shielding is a conducting enclosure which separates the space into two spaces that have to be magnetically isolated from one another. The object of a magnetic shielding is twofold: it serves the purpose both of containing the magnetic fields within the shielded enclosure and of preventing external magnetic fields from entering the enclosure.

For this, the material used to make the magnetic shielding has to be able to attract, concentrate and divert the magnetic field lines to prevent them from passing in a given volume. Magnetic shieldings are achieved by means of ferromagnetic materials having a high magnetic susceptibility and a weak coercitive field strength. They have a high relative magnetic permeability and can for example be made from soft iron or from permalloy. What is meant by high relative magnetic permeability is μᵣ>1000.

The quality of a magnetic shielding is essential in the field of magneto-cardiography, i.e. the study of the electric activity of the myocardium cells. In order to make correct and reliable measurements, it is of paramount importance that the person who is undergoing the medical examination be isolated from any external magnetic field able to disturb the measurements made.

However the magnetic domains of the material used to perform the shielding may be impaired by the effect of a mechanical or thermal shock, resulting in the efficiency of the magnetic shielding being reduced.

### OBJECT OF THE INVENTION

One object of the invention is to provide a magnetic shielding having performances that are improved and sustained in time.

For this purpose, the invention concerns a magnetic shielding comprising at least one side wall defining a cavity to contain an object to be magnetically isolated. The side wall comprises at least one layer of ferromagnetic metallic material and at least one layer of polymer material comprising a ferromagnetic powder.

According to a particular embodiment, at least one of the metallic layers and at least one of the polymer layers have a common interface.

In preferred manner, the magnetic shielding can comprise between three and five metallic layers and between three and five polymer layers comprising a ferromagnetic powder, two adjacent metallic layers being separated by a layer of polymer material.

According to an advantageous feature of the invention, the magnetic shielding can comprise an external polymer layer comprising a ferromagnetic powder.

The materials of the ferromagnetic metallic layers and of the ferromagnetic powder can be chosen from soft iron, permalloy, iron and/or nickel and/or cobalt alloys, and ferrites. The polymer material can for its part be chosen from epoxy resin, elastomers or low-density polyethylene.

The thickness of at least one of the layers of polymer material can be comprised between 1 mm and 10 cm.

### BRIEF DESCRIPTION OF THE DRAWINGS

Other advantages and features will become more clearly apparent from the following description of a particular embodiment of the invention given for non-restrictive example purposes only and represented in the appended drawing, which illustrates a cross-sectional view of a cylindrical magnetic shielding in schematic manner.

### DETAILED DESCRIPTION

To magnetically isolate an object from an outside environment, the latter can be placed in a cavity the walls of which form a magnetic shielding. The walls of the cavity can be formed by means of a layer of machined ferromagnetic metal to achieve the required shape (cylindrical, spherical, rectangular, etc.).

Machining does however make the structure of the ferromagnetic metallic layer fragile on the atomic scale, which limits its efficiency as magnetic shielding. The metallic layer then undergoes one or more heat treatments the purpose of which is to improve the crystalline structure of the material and to eliminate the impurities present in the material (carbide, sulphide, nitrides) which could limit the quality of the shielding.

During this heat treatment step, the ferromagnetic metallic layer is generally subjected to a temperature comprised between 1000 and 1200° C. for a time comprised between 1 and 6 h. Then the temperature is reduced in controlled manner to prevent weakening of the material.

After heat treatment, the mechanical and thermal resistance of the metallic layer is lower, and mechanical or thermal shocks may impair the quality of the shielding. It is therefore of paramount importance to handle the metallic layer with care and to not subject the latter to sharp temperature variations in order not to impair its efficiency in time.

To improve the quality of the magnetic shielding, the cavity can be made by association of several ferromagnetic metallic layers separated by wedges or by foam sheets. These elements do however exert mechanical stresses on the metallic layers and impair the quality of the shielding.

Moreover in this type of device, the thickness of the metallic layers is generally comprised between 1 and 3 mm and the thickness of the foam layers is about 1 to 5 cm. Such a device can therefore be bulky.

The invention therefore consists in making a cavity 1 having walls resistant to thermal and mechanical shocks, and having a limited size compared with a device comprising metallic layers and foam layers.

For this purpose, the cavity 1 comprises at least one ferromagnetic metallic layer 2 surrounded by at least one polymer material layer 3 comprising a ferromagnetic powder.

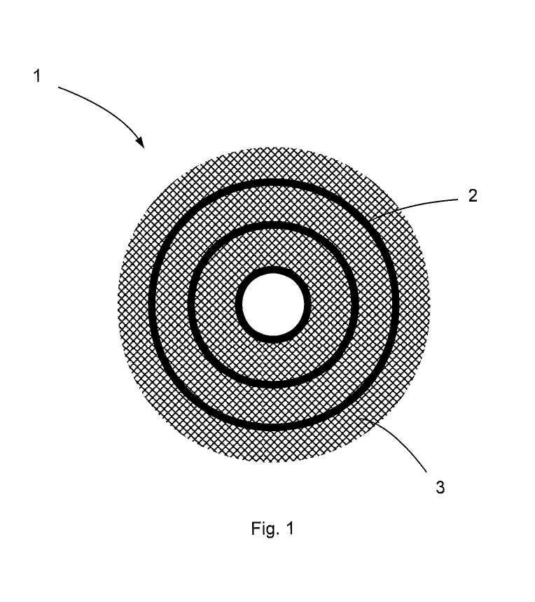

The ferromagnetic metallic layers 2 and polymer layers 3 comprising a ferromagnetic powder can be achieved in different forms according to the required quality of the magnetic shielding. The layers can for example be cylindrical as in the embodiment of FIG. 1, schematically illustrating a cross-sectional view of a cavity 1 of cylindrical shape. Cavity 1 can also be rectangular or spherical, or have any shape if this is preferable for the magnetic shielding to be more efficient.

At least one of the metallic layers 2 can be in contact with at least one of the polymer material layers 3 so as to limit the gaps between the different elements composing the device, thereby enhancing its compactness. The metallic layers 2 and polymer material layers 3 can therefore have a common interface.

The metallic layers 2 and polymer layers 3 can be arranged alternately for each polymer layer 3 to act as thermal and mechanical damper with respect to the metallic layers 2 which are located on each side of the polymer layer 3 involved.

To obtain an efficient magnetic shielding without the cost of the latter being prohibitive, the walls of the cavity 1 can contain between three and five ferromagnetic metallic layers 2 and between three and five polymer layers 3 each comprising a ferromagnetic powder, two adjacent metallic layers 2 being able to be separated by a polymer material layer 3.

The inventors in fact observed that the efficiency of the shielding is notably improved when the device 1 alternately comprises three metallic layers 2 and three layers 3 comprising a ferromagnetic powder, compared with a device 1 alternately comprising two metallic layers 2 and two polymer layers 3 comprising a ferromagnetic powder.

The metallic layers 2 can be made from identical or different materials. For the sake of simplicity of the fabrication, the material can be identical for all the metallic layers 2. However, it can be envisaged to use materials having a very high relative magnetic permeability in the outer part of the device 1, and to use materials having a lower relative magnetic permeability in the inner part. In this way, the magnetic field lines are diverted all the more efficiently as they are located in the outer part of the device 1. The metallic layers 2 can for example be made from soft iron, permalloy, ferrite or alloys having a base formed by iron and/or nickel and/or cobalt.

The polymer material layers 3 have a thickness advantageously comprised between 1 mm and 10 cm. For example, in the case of a shielding suitable to be used in magneto-cardiography, the polymer material layers 3 can have a thickness of 1 to 10 cm. They can for example be fabricated from epoxy resin, elastomer or low-density polyethylene. In the same way as for the metallic layers 2, the polymer layers 3 can be made from different materials, even if, for reasons of simplicity of fabrication, the polymer layers 3 are preferably identical.

The materials used for fabricating the polymer layers 3 present the advantage of being inexpensive and of being able to withstand large elastic deformations before breaking. The polymer layers 3 can therefore withstand mechanical shocks without their structure being impaired.

Adding ferromagnetic powder to the polymer layer 3 gives the polymer layer 3 ferromagnetic properties and therefore contributes to the magnetic shielding. The ferromagnetic powder can have a base formed by iron, permalloy or ferrite, or be a mixture having a base formed by iron and/or nickel and/or cobalt. It can for example consist of a soft iron powder, a mumetal powder (Fe, Ni, Cu, Mo alloy), or an amorphous metal.

According to an advantageous embodiment, the outermost part of the wall of cavity 1 can be formed by a layer of polymer material comprising a ferromagnetic powder. This powder can advantageously have a high relative magnetic permeability and for example be made from soft iron so as to notably reduce the magnetic field at the level of the inner layers of cavity 1.

Making an outer enclosure made from polymer material on the outermost part of the walls of the cavity 1 also improves the resistance of the magnetic shielding to thermal shocks. The polymer material layer then acts as thermal insulator for the metallic layers 2 used for fabricating the magnetic shielding.

The document entitled “Enhancement of the Relative Magnetic Permeability of Polymeric Composites with Hybrid Particulate Fillers” (Fiske et al., Journal of Applied Polymer Science, 1997) gives the value of the relative magnetic permeability of several polymers charged with ferromagnetic powder. For example a mixture named A, comprising 35% volume of low-density polyethylene, 50% volume of NiZn ferrite and 15% volume of amorphous metal such as Metglas® in powder form has a relative magnetic permeability of about 100. A mixture named B, comprising 90% volume of low-density polyethylene and 10% volume of amorphous metal such as Metglas® in powder form has a relative magnetic permeability of about 30. For comparison purposes, the relative magnetic permeability of low-density polyethylene is about 1.

Mixtures A and B can be used to replace the wedges or the foam sheets placed between the metallic layers of a magnetic shielding device according to the prior art. For example, for a cylindrical shielding alternately comprising a metallic layer and a polymer layer charged with ferromagnetic powder, 1 mm of mumetal associated with 1 cm of mixture A has an efficiency equivalent to 1 mm of mumetal associated with 3.3 cm of mixture B. A device according to the prior art having an equivalent efficiency would correspond to a metallic layer of 2 mm of mumetal associated with wedges or with foam sheets of several centimetres.

The use of a polymer layer charged with ferromagnetic powder therefore enables a more compact device to be obtained as all the volume occupied by the device is used for the purpose of shielding, unlike devices comprising foam layers or wedges which are elements that do not contribute to the magnetic shielding.

The production cost of this device is also less high at equivalent efficiency, as it is more inexpensive to use a ferromagnetic powder of a plate of an equivalent material.

This type of shielding is particularly suitable for isolating an object from a magnetostatic field. To achieve an optimal electromagnetic shielding, the ferromagnetic powder contained in the polymer material layer can be replaced by a conducting powder so as to obtain an electrically conducting polymer layer. The walls of the cavity 1 could therefore be designed to perform both magnetostatic and electromagnetic shielding, for example by placing polymer layers 3 containing a ferromagnetic powder and polymer layers containing conducting powders between the metallic layers 2.

1-7. (canceled)

8. A magnetic shielding comprising at least one side wall defining a cavity to contain an object to be magnetically isolated, the side wall comprising between three and five layers of ferromagnetic metallic material and between three and five layers of polymer material comprising a ferromagnetic powder, two adjacent metallic layers being separated by a polymer material layer.

9. Magnetic shielding according to claim 8, wherein at least one of the metallic layers and at least one of the polymer layers have a common interface.

10. Magnetic shielding according to claim 8, wherein the outer part of the side wall is formed by a polymer material layer.

11. Magnetic shielding according to claim 8, wherein the material of the metallic layer is chosen from soft iron, permalloy, iron and/or nickel and/or cobalt alloys, and ferrites.

12. Magnetic shielding according to claim 8, wherein the polymer material is chosen from elastomers, epoxy resin, or low-density polyethylene.

13. Magnetic shielding according to claim 8, wherein the ferromagnetic powder is chosen from soft iron, permalloy, iron and/or nickel and/or cobalt alloys, and ferrites.

14. Magnetic shielding according to claim 8, wherein the thickness of at least one of the polymer material layers is comprised between 1 mm and 10 cm.
